(19) United States
(12) Patent Application Publication
(10) Pub. No.: US 2010/0252909 A1
(43) Pub. Date: Oct. 7, 2010

(54) Three-Dimensional Memory Devices

(76) Inventors: Toshiro Nakanishi, Seongnam-si (KR); Jeonghee Han, Hwaseong-si (KR); Soodoo Chae, Yongin-si (KR)

Correspondence Address: MYERS BIGEL SIBLEY & SAJOVEC, PO BOX 37428, RALEIGH, NC, 27627, US

(21) Appl. No.: 12/754,913

(22) Filed: Apr. 6, 2010

(30) Foreign Application Priority Data
Apr. 6, 2009 (KR) 10-2009-0029590

(51) Int. Cl. H01L 27/06; H01L 29/92; H01L 29/8605

(52) U.S. Cl. 257/532; 257/536; 257/E29.326; 257/E29.342; 257/E27.026

(57) ABSTRACT

An integrated circuit memory device may include a semiconductor substrate and a plurality of word-line layers wherein adjacent word-line layers are separated by respective word-line insulating layers. A plurality of active pillars may extend from a surface of the semiconductor substrate through the plurality of word-line layers and insulating layers. Dielectric information storage layers may be provided between the active pillars and the respective word-line layers. Related methods of operation and fabrication are also discussed.

### CROSS-REFERENCE TO RELATED APPLICATION

This U.S. non-provisional patent application claims the benefit of priority under 35 U.S.C. §119 of Korean Patent Application 10-2009-0029590, filed on Apr. 6, 2009, the entire disclosure of which is hereby incorporated by reference.

### BACKGROUND

The present disclosure herein relates to semiconductor memory devices, and more particularly, to three-dimensional memory devices.

Increases of integration density of semiconductor devices are desired to increase performance and/or reduce price. In semiconductor memory devices, integration density is a significant factor in determining prices. In traditional two-dimensional or planar semiconductor memory devices, integration density is primarily determined by an area occupied by a unit memory cell which is greatly influenced by techniques used to form fine patterns. However, since high-priced equipment may be required to form fine patterns, increases in integration density of two-dimensional memory semiconductor devices may be limited.

As alternatives to increasing integration density, techniques to form three-dimensional memory cells have been developed. Because the memory cells are formed in three-dimensions, the area of a semiconductor substrate may be more effectively utilized. As a result, the integration density may increase significantly as compared to traditional two-dimensional semiconductor memory devices. In addition, these techniques may be based on forming word lines using a patterning process to define an active region, thereby reducing a manufacturing cost per a bit.

### SUMMARY

According to some embodiments of the present invention, an integrated circuit memory device may include a semiconductor substrate, and a plurality of word-line layers and word-line insulating layers wherein adjacent word-line layers are separated by respective word-line insulating layers. A plurality of active pillars may extend from a surface of the semiconductor substrate through the plurality of word-line layers and word-line insulating layers. In addition, dielectric information storage layers may be provided between the active pillars and the respective word-line layers.

According to other embodiments of the present invention, a method of electronically storing data may include providing an integrated circuit memory device structure including a semiconductor substrate, a plurality of word-line layers and word-line insulating layers wherein adjacent word-line layers are separated by respective word-line insulating layers, a plurality of active pillars extending from a surface of the semiconductor substrate through the plurality of word-line layers and word-line insulating layers, and dielectric information storage layers between the active pillars and the respective word-line layers. A program voltage may be applied to a selected word-line layer, and a pass voltage may be applied to a non-selected word-line layer wherein the program and pass voltages are different. While applying the program and pass voltages to the selected and non-selected word-line layers, a breakdown voltage greater than the program voltage may be applied to a selected active pillar to provide dielectric breakdown through a dielectric information storage layer between the selected word-line layer and the selected active pillar.

According to still other embodiments of the present invention, a method of forming an integrated circuit memory device may include forming a plurality of word-line layers and word-line insulating layers on a semiconductor substrate wherein adjacent word-line layers are separated by respective word-line insulating layers. An array of openings may be formed through the word-line layers and the word-line insulating layers exposing portions of the substrate, and dielectric information storage layers may be formed on sidewalls of the openings. After forming the dielectric information storage layers, an array of active pillars may be formed in the openings so that the dielectric information storage layers are between the active pillars and the respective word-line layers.

A three-dimensional memory device according to some embodiments of the present invention may provide increased capacity and/or reduced manufacturing cost.

According to some embodiments of the present invention, a three-dimensional memory device may include a semiconductor substrate with a common source region. Planar word lines and inter-gate insulating layers may be alternately stacked on the semiconductor substrate. Active pillars may penetrate the planar word lines and the inter-gate insulating layers and may extend upward from the semiconductor substrate. Information storage layers may be interposed between the active pillars and the planar word lines. In this case, the information storage layers may be subjected to breakdown to store data.

The information storage layers may include a silicon oxide layer. The three-dimensional memory device may further include ion implantation layers interposed between the planar word lines and the information storage layers. The planar word lines may include polysilicon with a first conductivity type dopant, and the ion implantation layers may include polysilicon with a second conductivity type dopant. The ion implantation layers and the planar word lines may form a diode. The first conductivity type dopant may be an N-type dopant and the second conductivity type dopant may be a P-type dopant.

The three-dimensional memory device may further include lower selection lines extending in a first direction on the semiconductor substrate. String selection lines may intersect the lower selection lines and extend in a second direction. The lower selection lines and the string selection lines may be disposed between the lowest layer of the planar word lines and the semiconductor substrate. The lower selection lines and the string selection lines may contain metal.

Storing data may include applying a program voltage and a pass voltage to selected planar word lines and non-selected planar word lines, respectively. A breakdown voltage higher than the program voltage may be applied to the common source region to break down a selected information storage layer.

Storing data may further include selecting a memory cell string formed by the active pillars and the planar word lines. Selecting the memory cell string may include applying a turn-on voltage to any one of the lower selection lines and applying the turn-on voltage to any one of the string selection lines.

Reading the stored data may include applying a reading voltage and a reverse bias voltage to the selected planar word lines and the non-selected planar word lines, respectively. A reference voltage may be applied to the common source region. The reference voltage may be higher than the reading voltage and lower than the reverse bias voltage.

### BRIEF DESCRIPTION OF THE DRAWINGS

The accompanying drawings are included to provide a further understanding of embodiments of the present invention, and are incorporated in and constitute a part of this specification. The drawings illustrate embodiments of the present invention and, together with the description, serve to explain principles of the present invention. In the drawings:

FIGS. 1 and 2 are perspective and cross-sectional views illustrating a three-dimensional memory device according to some embodiments of the present invention;

FIG. 3 is a circuit diagram illustrating the three-dimensional memory device according to some embodiments of the present invention;

FIGS. 4A through 4D are cross-sectional views illustrating operations of forming three-dimensional memory devices according to some embodiments of the present invention;

FIG. 5 is a block diagram illustrating an electronic system including a three-dimensional memory device according to some embodiments of the present invention; and

FIG. 6 is a block diagram illustrating a memory card including a three-dimensional memory device according to some embodiments of the present invention.

### DETAILED DESCRIPTION

Advantages and features of the present invention and methods of accomplishing the same may be understood more readily by reference to the following detailed description of embodiments and the accompanying drawings. The present invention may, however, be embodied in many different forms and should not be construed as being limited to embodiments set forth herein. Rather, these embodiments are provided so that this disclosure will be thorough and complete and will fully convey the concept of the invention to those skilled in the art, and the present invention will only be defined by the appended claims. Like reference numerals refer to like elements throughout the specification.

It will be understood that when an element is referred to as being “connected to” or “coupled to” another element, it can be connected or coupled to the other element or intervening elements may be present. In contrast, when an element is referred to as being “directly connected to” or “directly coupled to” another element, there are no intervening elements present. Like numbers refer to like elements throughout. As used herein, the term “and/or” includes any and all combinations of one or more of the associated listed items.

It will be understood that, although the terms first, second, etc. may be used herein to describe various elements, components, and/or sections, these elements, components, and/or sections should not be limited by these terms. These terms are only used to distinguish one element, component or section from another element, component, or section. Thus, a first element, component, or section discussed below could be termed a second element, component, or section without departing from the teachings of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In addition, when terms used in this specification are not specifically defined, all the terms used in this specification (including technical and scientific terms) can be understood by those skilled in the art. Further, when general terms defined in the dictionaries are not specifically defined, the terms will have the normal meaning in the art.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

In the drawings, the illustrated features may be changed due to, for example, the manufacturing technology and/or tolerance. Accordingly, it should be understood that the example embodiments discussed herein are not limited to the drawings but include modifications of the features of elements caused due to, for example, the manufacture.

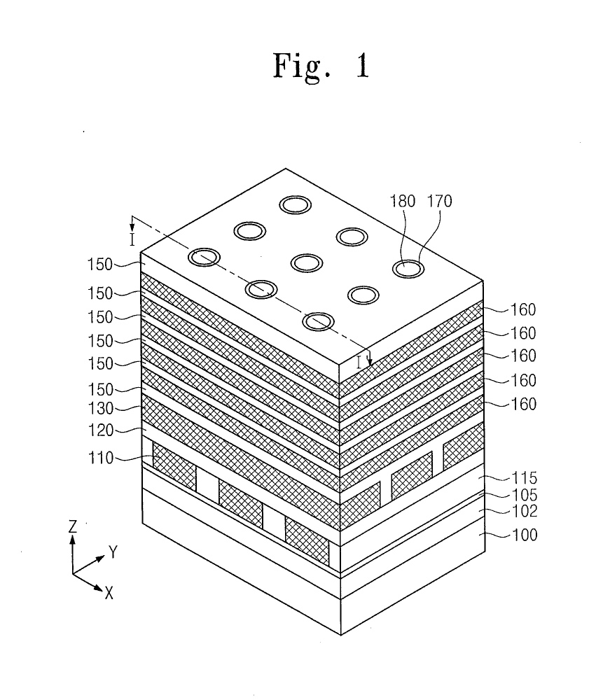

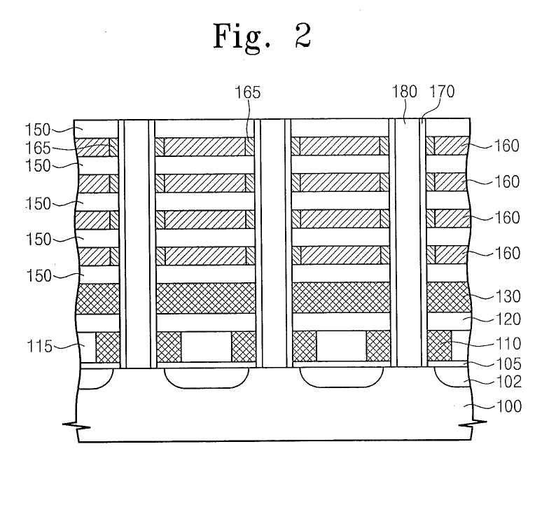

FIGS. 1 and 2 are plan and cross sectional views illustrating a three-dimensional memory device according to some embodiments of the present invention.

Referring to FIGS. 1 and 2, a first insulating layer 105 is disposed on a semiconductor substrate 100 including a common source region 102. The common source region 102 may be connected electrically to a source electrode (not illustrated). Planar word lines 160 (also referred to as word-line layers) and inter-gate insulating layers 150 (also referred to as word-line insulating layers) are alternately stacked on the semiconductor substrate 100. The planar word lines 160 may include polysilicon. The inter-gate insulting layers 150 may include an insulating material such as a silicon oxide.

Active pillars 180 are disposed to penetrate the planar word lines 160 and the inter-gate insulating layers 150 and extend upward from the semiconductor substrate 100. The active pillars 180 may be formed of a semiconductor material and may have a single-crystal structure, a poly-crystal structure, and/or an amorphous crystal structure.

Information storage layers 170 are disposed between the active pillars 180 and the planar word lines 160, respectively. Each information storage layer 170 may be a silicon oxide layer. The information storage layer 170 does not trap or store charges, but stores data by a dielectric breakdown. The dielectric breakdown or the breakdown of the information storage layer 170 means that a breakdown path with higher conductivity is formed through the information storage layer 170 between a planar word-line 160 and an active pillar 180. Accordingly, the three-dimensional memory device may be a ROM device which is programmable once. An information storage layer 170 thus defines a memory cell at each intersection with a planar word line 160. As initially formed, a memory cell may have a first (relatively high resistance) memory state, and the memory cell may be programmed once to a second (relatively low resistance memory state) by subjecting the information storage layer 170 to dielectric breakdown at the intersection between the respective planar word-line and active pillar.

Doped layers 165 may be interposed between the information storage layers 170 and the planar word lines 160. The planar word lines 160 may include polysilicon with a first conductive type dopant and the doped layers 165 may include polysilicon with a second conductive type dopant. The first conductive type dopant may be N-type dopant and the second conductive type dopant may be P-type dopant. The doped layers 165 and the planar word lines 160 may thus form PN junction diodes. Stated in other words, doped layers 165 may have the second conductivity type and the planar word lines 160 may have the first conductivity type.

Lower selection lines 110 and string selection lines 130 may be disposed between the semiconductor substrate 100 and the lowest of the planar word lines 160. The lower selection lines 110 may be disposed to extend in a first direction. The string selection lines 130 may be disposed between the lower selection lines 110 and the lowest of the planar word lines 160 to extend in a second direction. The first direction may be an X-direction (illustrated in FIG. 1) and the second direction may be a Y-direction (illustrated in FIG. 1) that is perpendicular with respect to the X-direction. The lower selection lines 110 and/or the string selection lines 130 may include metal, unlike the planar word lines 160. A second insulating layer 115 is disposed between the lower selection lines 110 and on the first insulating layer 105. A third insulating layer 120 is disposed on the lower selection lines 110 and the second insulating layer 115. The active pillars 180 are disposed to penetrate the lower selection lines 110 and the string selection lines 130.

The planar word lines 160 may be disposed closely so that reversion regions overlap with each other due to a fringing field of applied voltages. The gate inter-layer insulating layers 150 may have a thickness so that reversion regions overlap with each other by the fringing field due to the planar word lines 160. According to some embodiments of the present invention, plural memory cells may be formed by the planar word lines 160 sharing one active pillar, and the plural memory cells along one active pillar may form one string. The lower selection lines 110, the common source region 102, and one active pillar may form a transistor. This transistor may be termed a lower selection transistor. Likewise, the string selection lines 130 and one active pillar 180 may form a string selection transistor.

A three-dimensional memory device according to some embodiments of the present invention stores data by the breakdown of the information storage layer 170 at a respective word line 160. In some cases, it may not be necessary to execute programming plural times in an electronic apparatus requiring a large capacity memory device. A three-dimensional memory device according to some embodiments of the present invention may be capable of stacking memory cells to provide increased capacity.

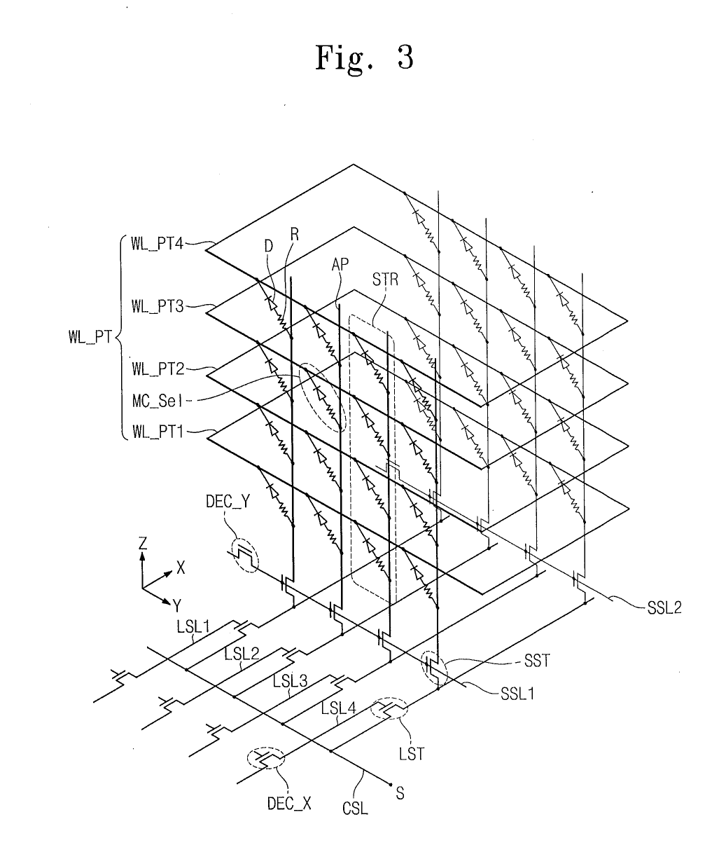

FIG. 3 is a circuit diagram illustrating the three-dimensional memory device according to some embodiments of the present invention.

Referring to FIG. 3, a three-dimensional memory device according to some embodiments of the present invention may include horizontally arranged planar word lines WL_PT and vertically arranged active pillars AP. The active pillars AP may have a major axis in a direction penetrating the planar word lines WL_PT. Intersection points between the planar word lines WL_PT and the active pillars AP may be distributed three-dimensionally. Memory cells MC of the three-dimensional memory device may be defined at the three-dimensionally distributed intersection points. As a result, one memory cell is defined by one active pillar AP and one planar word line WL_PT. The memory cells MC arranged along one active pillar AP may form one memory cell string STR.

In FIG. 3, active pillars AP may correspond to active pillars 180 of FIGS. 1 and 2. Planar word lines WL_PT may correspond to planar word lines 160 of FIGS. 1 and 2. String selection lines SSL1 and SSL2 may correspond to respective string selection lines 130 of FIGS. 1 and 2. Accordingly, string selection transistors SST may be defined at intersections of active pillars 180 and string selection lines 130, with string selection lines providing gate electrodes, with layers 170 providing gate insulating layers, and with active pillars 180 providing source, drain, and channel regions.

Common source line CSL may correspond to common source region 102 providing a common source for lower selection transistors LST. Lower selection lines LSL may correspond to lower selection lines 110 providing gate electrodes for lower selection transistors LST. Gate insulating layers of lower selection transistors LST may be provided by layers 105 and/or 170, and lower portions of active pillars 180 may provide drains of lower selection transistors LST. While one lower selection transistor LST is shown for each row of active pillars AP in FIG. 3 for ease of illustration, actual implementation may provide a different transistor LST at each pillar AP with rows of transistors LST sharing a same lower selection line LSL as a common gate.

To write and read one memory cell selectively, one memory cell string STR has to be selected independently. Therefore, lower selection lines LSL1 to LSL4 and string selection lines SSL1 and SSL2 may be disposed between the memory cell strings STR and substrate 100 (including common source line CSL). Voltages may be applied selectively to the lower selection lines LSL1 to LSL4 by X-direction decoders DEC_X. The lower selection lines LSL1 to LSL4, the common source line CSL, and the active pillars AP form lower selection transistors LST. Accordingly, the lower selection lines LSL1 to LSL4 may turn on or turn off electrical connection between the common source line CSL and the active pillars AP.

The string selection lines SSL1 and SSL2 may be disposed between the lower selection transistor LST and the memory cell string STR. Voltages may be applied to the string selection lines SSL1 and SSL2 by a Y-direction decoder DEC_Y. Likewise, the string selection lines SSL1 an SSL2 and the active pillars AP may form the string selection transistors SST. Accordingly, one selection line and one string selection line may independently control one memory cell string STR.

The common source line CSL may form a current path directed toward a memory cell string STR. The common source line CSL may correspond to the common source region 102 illustrated in FIGS. 1 and 2. The common source line CSL may be doped to have a conductivity type different from that of the substrate and the active pillar AP and may be connected electrically to a source electrode S. A voltage applied to the common source line CSL may not be applied directly to the active pillar AP.

A doped layer may be interposed between the active pillars AP and the planar word lines WL_PT. The doped layers (e.g., doped layer 165) and the planar word lines WL_PT (e.g., planar word-lines 160) may define diodes D (i.e., P-N junctions). The information storage layer (e.g., information storage layer 170) between the doped layer and the active pillar AP is expressed as a resistor R.

A controller (including X-direction and Y-direction decoders DEC_X and DEC_Y) may be coupled to planar word lines WL_PT, lower selection lines LSL1-4, string selection lines SSL1-2, and common source line CSL. As discussed in greater detail below, such a controller may generate/sense signals used for read and write operations.

Referring to FIGS. 1 through 3, a method of operating the three-dimensional memory device according to some embodiments of the present invention will be described.

### Program Operation Method

A program operation method of the three-dimensional memory device may be provided to store data in a selected memory cell MC_sel. A program voltage is applied to the planar word line WL_PT3 of the selected memory cell MC_sel and a pass voltage is applied to the planar word lines WL_PT1, WL_PT2, and WL_PT4 of the non-selected memory cells. The memory cell string STR of the selected memory cell MC_sel is selected and a breakdown voltage is applied to the active pillar 180 to break down the information storage layer 170 of the selected memory cell MC_sel. That is, the program voltage and the breakdown voltage form a conductive breakdown path through the information storage layer 170.

The program voltage is lower than the breakdown voltage. This is because the doped layers 165 and the planar word lines 160 form a diode. The pass voltage forms a reversion region in the active pillar 180 of non-selected memory cells.

The selecting of the memory cell string STR includes applying a turn-on voltage to one lower selection line LSL2 so that the lower selection transistor LST is turned on and applying a turn-on voltage to one string selection line SSL1 so that the string selection transistor SST is turned on.

### Reading Method

Next, a method of reading the data stored in the selected memory cell MC will be described. A reading voltage is applied to the planar word line WL_PT3 of the selected memory cell MC_sel and a reverse bias voltage is applied to the non-selected planar word lines WL_PT1, WL_PT2, and WL_PT4). A reference voltage is applied to the common source line CSL. The reference voltage is higher than the reading voltage and is lower than the reverse bias voltage. This is because the diode formed by the ion implantation layers and the planar word lines has a rectification function. That is, little or no current flows in the memory cell, to which the reverse bias voltage and the reference voltage are applied, due to diode D, whereas a current may flow in the memory cell MC_sel, to which the reading voltage and the reference voltage are applied, due to a forward bias of diode D. Therefore, information may be read by detecting a current generated by a voltage difference between the reading voltage and the reference voltage.

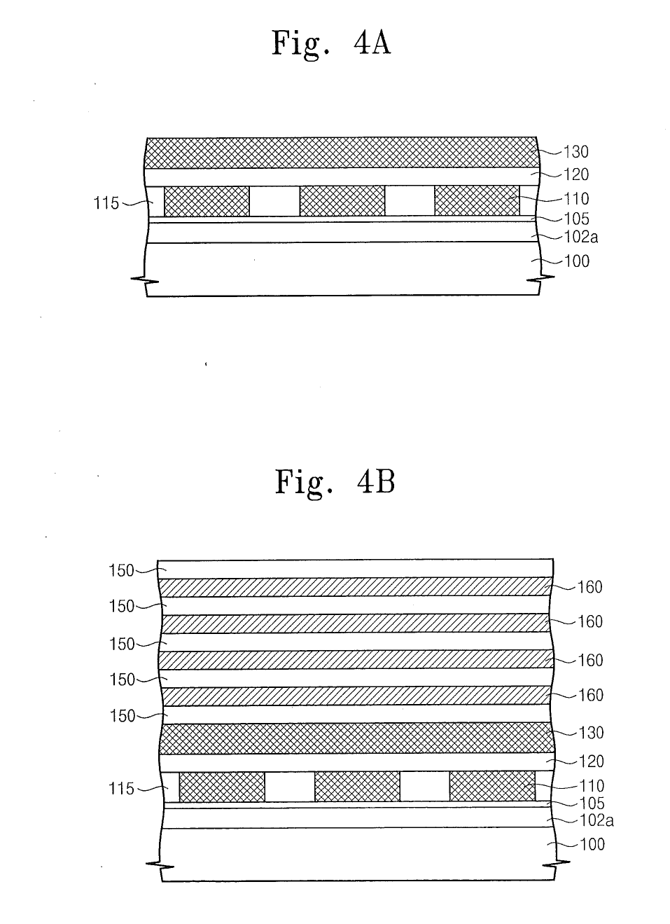

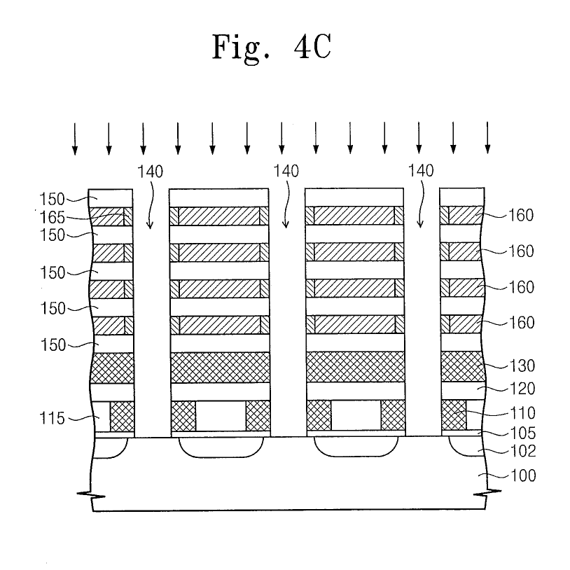

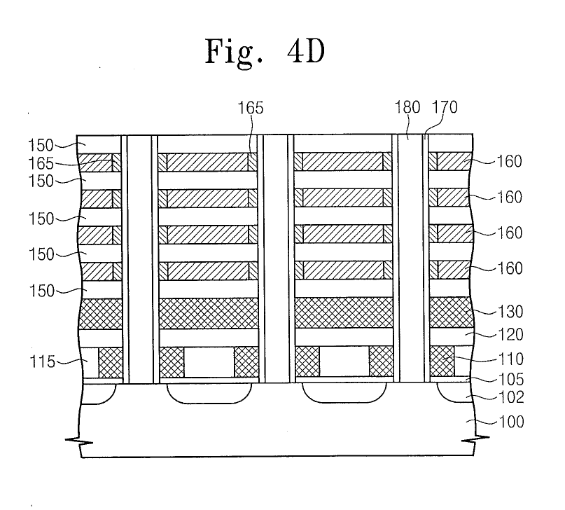

FIGS. 4A through 4D are cross-sectional views illustrating methods of forming a three-dimensional memory device according to some embodiments of the present invention.

Referring to FIG. 4A, a preliminary common source line 102a is formed on the semiconductor substrate 100. The preliminary common source line 102a may be formed using ion implantation to have a conductive dopant, for example, N-type dopant, opposite to that of the semiconductor substrate 100. Accordingly, substrate 100 may have p-type conductivity, and common source line 102a may have n-type conductivity. A first insulating layer 105 is formed on the semiconductor substrate 100. The first insulating layer 105 may be formed of an insulating material such as a silicon oxide.

A second insulating layer 115 is formed on the first insulating layer 105. The lower selection lines 110 are formed in the second insulating layer 115. The lower selection lines 110 may be patterned from a metal layer(s). A third insulating layer 120 is formed on the lower selection lines 110 and the second insulating layer 115. The string selection lines 130 are formed on the third insulating layer 120. Like the lower selection lines 110, the string selection lines 130 may be patterned from a metal layer(s).

Referring to FIG. 4B, the inter-gate insulating layers 150 and the planar word lines 160 are alternately stacked on the string selection lines 130. The planar word lines 160 may be formed of polysilicon. The planar word lines 160 may be doped with N-type dopants so as to have n-type conductivity. The inter-gate insulating layers 150 may be formed with a relatively thin thickness so that reversion regions overlap with each other by the fringing field of the voltage applied to the planar word lines 160.

Referring to FIG. 4C, openings 140 penetrate the inter-gate insulting layers 150, the planar word lines 160, the string selection lines 130, and the lower selection lines 110 to expose portions of the semiconductor substrate 100. The doped layers 165 are formed by supplying dopant to the entire surface of the semiconductor substrate 100, after the openings 140 are formed. Dopant may be provided to portions of substrate 100 (exposed through the openings 140) in the preliminary common source line 102a, and these portions may be doped so as to have the same conductivity type as that of the semiconductor substrate 100. Accordingly, remaining portions of the preliminary common source line 102a may be deformed to provide the common source line 102. The dopant may be a P-type dopant to provide p-type conductivity. The doped layer 165 may be formed at portions of the planar word lines 160 exposed by openings 140 to provide the PN junction diodes. Supplying the dopant may include supplying a source gas and performing a heat treatment. The source gas may be B₂H₆ or the like.

Referring to FIG. 4D, the information storage layers 170 are formed on inner surfaces of the openings 140. The information storage layers 170 may have a thickness sufficient to be subjected to dielectric breakdown or breakdown by the program voltage and the breakdown voltage described with reference to FIG. 3. The information storage layers 170 may be formed of silicon oxide. The information storage layers 170 may be conformally formed using a chemical vapor deposition. Portions of information storage layers 170 on the bottom surfaces of the openings 140 are removed.

The active pillars 180 are formed in openings 140 after forming information storage layers 170. According to embodiments of the present invention, the active pillars 180 may be formed of single-crystal silicon. In this case, the active pillars 180 may be formed to fill the openings 140 using epitaxial growth. According to other embodiments, the active pillars 180 may be formed of poly-crystal silicon or amorphous silicon. In this case, the active pillars 180 may be formed to fill the openings 140 using a chemical vapor deposition.

According to modified embodiments of the present invention, the active pillars 180 may be formed to conformally cover the opening 140 in which the information storage layers 170 are formed. In this case, the active pillar 180 may be formed in a columnar or shell shape and an insulating material may filled an inner space of the active pillar 180. The thickness of the active pillar 180 may be smaller than an average length of grains of poly-crystal silicon.

According to embodiments of the present invention, since the information storage layer 170 is formed as a single layer, manufacturing cost may be reduced, compared to other three-dimensional memory devices formed of multiple layers (for example, oxide layer-nitride layer-oxide layer). Accordingly, three-dimensional devices according to embodiments of the present invention may provide relatively high capacity at a relatively low cost.

Three-dimensional memory devices according to the above-described embodiments may be realized in various types of semiconductor packages. For example, the three-dimensional memory device may be packaged as: package on package (PoP), ball grid array (BGAs), chip scale package (CSP), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small-outline integrated circuit (SOIC), shrink small-outline package (SSOP), thin small-outline package (TSOP), thin quad flat pack (TQFP), system in package (SIP), multi chip package (MCP), wafer-level fabricated package (WFP), or wafer-level processed stack package (WSP). A package mounted with a three-dimensional memory device according to embodiments of the present invention may further include a controller and/or a logic device, for example, controlling the three-dimensional memory device.

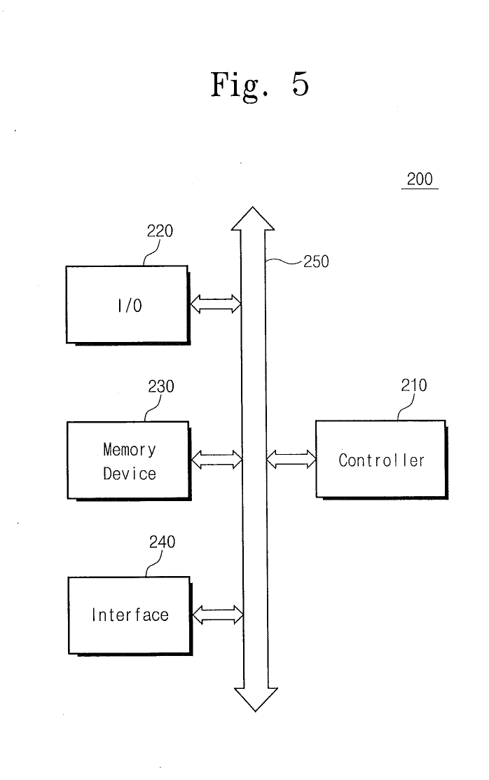

FIG. 5 is a block diagram illustrating an electronic system including the three-dimensional memory device according to embodiments of the present invention.

Referring to FIG. 5, an electronic system 200 may include a controller 210, an input/output device (I/O) 220, a memory device 230, an interface 240, and a bus 250. The controller 210, the input/output device (I/O) 220, the memory device 230, and/or the interface 240 may be connected to each other through the bus 250. The bus 250 is a transfer path of data.

The controller 210 includes at least one of a microprocessor, a digital signal processor, a microcontroller, and logic devices executing similar functions thereof. The I/O device 220 may include a key pad, a keyboard, or a display device. The memory device 230 may include the three-dimensional memory device disclosed in the above-described embodiments of the present invention. The memory device 230 may store data and/or commands, and the like. The memory device 230 may further include other types of semiconductor memory devices (for example, a phase change memory device, a magnetic memory device, a DRAM device, and/or an SRAM device). The interface 240 executes a function of transmitting data to a communication network or receiving data from a communication network. The interface 240 may be in the form of a wired or wireless interface. For example, the interface 240 may include an antenna or a wireless/wired transceiver. Even though not illustrated, the electronic system 200 may provide an operational memory improving the operation of the controller 210 and may further include a high-speed DRAM and/or a high-speed SRAM.

The electronic system 200 may be applicable to a personal digital assistant (PDA), a portable computer, a web tablet, a wireless phone, a mobile phone, a digital music player, a memory card, or any device capable of transmitting and/or receiving information in a wireless environment.

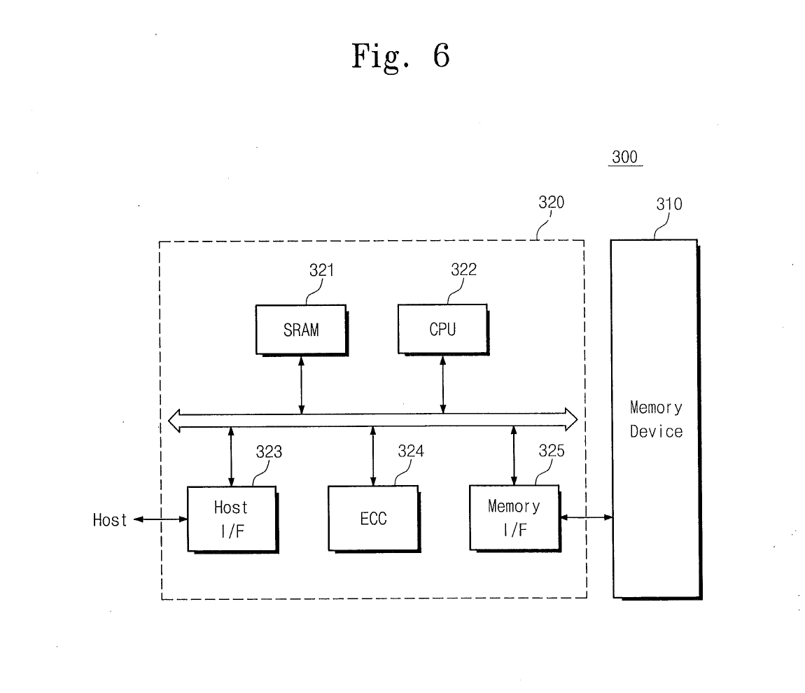

FIG. 6 is a block diagram illustrating a memory card including a three-dimensional memory device according to embodiments of the present invention.

Referring to FIG. 6, a memory card 300 according to embodiments of the present invention may include a memory device 310. The memory device 310 may include a three-dimensional memory device disclosed in the above-described embodiments. The memory device 310 may further include other types of semiconductor memory devices (for example, a phase change memory device, a magnetic memory device, a DRAM device, and/or an SRAM device). The memory card 300 may include a memory controller 320 controlling data exchange between a host and the memory device 310.

The memory controller 320 may include a processing unit 322 generally controlling the memory card. The memory controller 320 may include an SRAM 321 used as an operational memory of the processing unit 322. The memory controller 320 may further include a host interface 323 and a memory interface 325. The host interface 323 may have a protocol for exchanging data between the memory card 300 and a host. The memory interface 325 may connect the memory controller 320 to the memory device 310. The memory controller 320 may further include an error correction coding block (Ecc) 324. The error correction coding block 324 may detect and correct an error of data read from the memory device 310. Even though not illustrated, the memory card 300 may further include a ROM device storing code data used to interface with a host. The memory card 300 may be used as a portable data storing card. Alternatively, the memory card 300 may be realized as a solid state disk (SSD) replacing a hard disk drive of a computer system.

A three-dimensional memory device according to embodiments of the present invention may store data using breakdown (or not) of an information storage layer. The three-dimensional memory device may realize increased capacity by stacking the memory cells three-dimensionally.

Since the information storage layer is formed as a single layer, manufacturing cost may be reduced, compared to other three-dimensional memory devices formed of multiple layers (for example, oxide layer-nitride layer-oxide layer). Accordingly, a three-dimensional device according to embodiments of the present invention may be capable of achieving an increased capacity and reduced cost.

The above-disclosed subject matter is to be considered illustrative and not restrictive, and the appended claims are intended to cover all such modifications, enhancements, and other embodiments, which fall within the true spirit and scope of the inventive concept is to be determined by the broadest permissible interpretation of the following claims and their equivalents, and shall not be restricted or limited by the foregoing detailed description.

1. An integrated circuit memory device comprising:
a semiconductor substrate;
a plurality of word-line layers and word-line insulating layers wherein adjacent word-line layers are separated by respective word-line insulating layers;
a plurality of active pillars extending from a surface of the semiconductor substrate through the plurality of word-line layers and word-line insulating layers; and
dielectric information storage layers between the active pillars and the respective word-line layers.

2. An integrated circuit memory device according to claim 1 wherein each of the dielectric information storage layers comprises silicon oxide.

3. An integrated circuit memory device according to claim 1 wherein each of the word-line layers comprises a layer of a semiconductor material having a first conductivity type with regions of a second conductivity type surrounding each of the active pillars so that semiconductor P-N junctions in each of the word-line layers surround each of the active pillars extending through the respective word-line layer.

4. An integrated circuit memory device according to claim 3 wherein the first conductivity type is N-type conductivity and the second conductivity type is P-type conductivity.

5. An integrated circuit memory device according to claim 1 further comprising:
first selection lines extending in a first direction along respective rows of the active pillars; and
second selection lines extending in a second direction along respective columns of the active pillars,
wherein the first and second directions are different, and wherein the first and second selection lines are between the semiconductor substrate and the plurality of word-line layers.

6. An integrated circuit memory device according to claim 5 wherein the first and second selection lines comprise first and second metal selection lines, and wherein the dielectric information storage layers provide electrical isolation between the first and second selection lines and the respective active pillars.

7. An integrated circuit memory device according to claim 1 wherein the plurality of active pillars are arranged in an array of rows and columns of active pillars, and wherein each of the word-line layers is intersected by active pillars of different rows and by active pillars of different columns.

8. An integrated circuit memory device according to claim 7 wherein a first memory state is defined at a first memory cell by a relatively high electrical resistance through a first dielectric information storage layer between a first active pillar and a first word-line layer, and wherein a second memory state is defined at a second memory cell by a relatively low electrical resistance through a second dielectric information storage layer between a second active pillar and a second word-line layer.

9. An integrated circuit memory device according to claim 8 wherein the relatively low electrical resistance through the second dielectric information storage layer is provided by a dielectric breakdown through the second dielectric information storage layer between the second active pillar and the second word-line layer.

10.-20. (canceled)
